(19) United States
(12) Patent Application Publication
(10) Pub. No.: US 2025/0362342 A1
(43) Pub. Date: Nov. 27, 2025

(54) METHOD FOR TESTING A PACKAGING SUBSTRATE, AND APPARATUS FOR TESTING A PACKAGING SUBSTRATE

(71) Applicant: Applied Materials, Inc., Santa Clara, CA (US)

(72) Inventors: Axel WENZEL, Augsburg (DE); Edgar KEHRBERG, Haar (DE); Bernhard G. MUELLER, Finsing (DE)

(21) Appl. No.: 18/871,557

(22) PCT Filed: Jul. 8, 2022
(86) PCT No.: PCT/EP2022/069103

§ 371 Date: Dec. 4, 2024

(51) Int. Cl. G01R 31/307

(52) U.S. Cl. CPC G01R 31/307

(57) ABSTRACT

A method for testing a packaging substrate with at least one electron beam column is described. The packaging substrate is a panel level packaging substrate or an advanced packaging substrate. The method includes placing the packaging substrate on a stage in a vacuum chamber; flooding at least portions of the vacuum chamber with positive ions and/or negative charges; generating an electric field between one or more electrodes and the packaging substrate, the electric field being configured to accelerate the positive ions or the negative charges towards the substrate; and testing the packaging substrate in the vacuum chamber with at least one electron beam column.

### FIELD

The present disclosure relates to a method and an apparatus for testing a packaging substrate. More particularly, embodiments described herein relate to the contactless testing of electric interconnections in a packaging substrate, i.e. a panel-leveling packing (PLP) substrate or an advanced packaging (AP) substrate by using electron beams, particularly for identifying, characterizing, detecting and/or classifying defects such as shorts, opens, and/or leakages.

### BACKGROUND

In many applications, it is necessary to inspect a substrate to monitor the quality of the substrate. Since defects may e.g. occur during the processing of the substrates, e.g. during structuring or coating of the substrates, an inspection of the substrate for reviewing the defects and for monitoring the quality may be beneficial.

Semiconductor packaging substrates and printed circuits boards for the manufacture of complex microelectronic and/or micro-mechanic components are typically tested during and/or after manufacturing for determining defects, such as shorts or opens, in metal paths and interconnects provided at the substrate. For example, substrates for the manufacture of complex microelectronic devices may include a plurality of interconnect paths for connecting semiconductor chips or other electrical devices that are to be mounted on the packing substrate.

Various methods for testing such components are known. For example, contact pads of a component to be tested may be contacted with a contact probe, in order to determine whether the component is defective or not. Since the components and the contact pads are becoming smaller and smaller due to the progressing miniaturization of components, contacting the contact pads with a contact probe may be difficult, and there may even be a risk that the device under test gets damaged during the testing.

The complexity of packaging substrates is increasing and design rules (feature size) are decreasing substantially. Within such substrates the surface contact points (for later flip chip or other chip mounting) are connected to other surface contact points on the packaging substrate to interconnect semiconductor (or other) devices. Standard methods like electrical-mechanical probing for electrical test cannot satisfy the requirements of volume production testing as the throughput decreases (higher number of test points) and contacting reliability decreases (smaller contact size). Beyond the reduced size and the problem of potentially damaging contact pads, the topography of the packaging substrates results in difficulties for other test methods, like test methods utilizing capacitive detectors or electric field detectors, because such methods beneficially have a small mechanical spacing.

Accordingly, it would be beneficial to provide testing methods and testing apparatuses that are suitable for reliably and quickly testing complex microelectronic devices, particularly packaging substrates such as AP substrates and PLP substrates.

### SUMMARY

In light of the above, a method and apparatuses for testing a packaging substrate are provided according to the independent claims. Further aspects, advantages, and beneficial features are apparent from the dependent claims, the description, and the accompanying drawings.

According to an embodiment, a method for testing a packaging substrate with at least one electron beam column is provided. The packaging substrate is a panel level packaging substrate or an advanced packaging substrate. The method includes placing the packaging substrate on a stage in a vacuum chamber; flooding at least portions of the vacuum chamber with positive ions and/or negative charges; generating an electric field between one or more electrodes and the packaging substrate, the electric field being configured to accelerate the positive ions or the negative charges towards the substrate; and testing the packaging substrate in the vacuum chamber with at least one electron beam column.

According to an embodiment, an apparatus for testing a packaging substrate in accordance with a method of any of the embodiments described herein is provided. For example, a controller executes or performs a method of testing a packaging substrate with an electron beam column according to embodiments of the present disclosure.

According to an embodiment, an apparatus for contactless testing of a packaging substrate is provided. The apparatus includes a vacuum chamber; a stage within the vacuum chamber, the stage being configured to support the packaging substrate being a panel packaging substrate or an advanced packaging substrate; and a charged particle beam column configured to generate an electron beam. The charged particle beam column includes an objective lens configured to focus the electron beam on the packaging substrate; a scanner configured to scan the electron beam to different positions on the packaging substrate; and an electron detector for detecting signal electrons emitted upon impingement of the electron beam on the packaging substrate. The apparatus further includes one or more electrodes configured to generate an electric field between one or more electrodes and the packaging substrate, the electric field being configured to accelerate positive ions or negative charges towards the substrate; and an analysis unit for determining, based on the signal electrons, if a first device-to-device electrical interconnect path is defective.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus and a method for manufacturing the apparatuses and devices described herein. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic view of an apparatus for illustrating a charge control according to embodiments of the present disclosure;

FIG. 1B shows a schematic sectional view of an apparatus for testing a packaging substrate in accordance with any of the testing methods described herein;

FIGS. 2A and 2B show enlarged sectional views of packaging substrates during any of the testing methods described herein;

FIG. 3 shows an enlarged top view of a packaging substrate during any of the testing methods described herein;

FIGS. 4A-4D show enlarged sectional views of packaging substrates that can be tested according to the methods described herein;

FIGS. 5 and 6 show flowcharts of methods of testing a packaging substrate according to embodiments described herein; and

FIGS. 7A, 7B, and 7C show exemplary images illustrating the improvement of embodiments of the present disclosure.

### DETAILED DESCRIPTION

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations.

Within the following description of the drawings, the same reference numbers refer to same components. Only the differences with respect to the individual embodiments are described. The structures shown in the drawings are not necessarily depicted true to scale but rather serve the better understanding of the embodiments.

Embodiments of the present disclosure relate to testing and/or defect review for packaging substrates, i.e. panel-leveling packing (PLP) substrates or advanced packaging (AP) substrates, according to methods as described herein. At least one electron beam is used for writing and reading charges on the packaging substrate, particularly for identifying and characterizing defects such as shorts, opens, and/or leakages. A contactless electrical test with an electron beam can be provided, wherein a voltage signal reading, e.g. voltage contrast by signal electron sensing, is provided. According to some embodiments, which can be combined with other embodiments described herein, the voltage contrasts on the packaging substrate may be determined by detection of signal electrons. According to some embodiments, which can be combined other embodiments described herein, the signal electrons may particularly be secondary electrons. Further, test point or contact points can be charged contactless on an AP or PLP substrate. Contactless testing avoids or reduces damage to the AP/PLP substrate. Detection and classification of electrical defects is enabled. In order to further improve the voltage contrast in the methods according to embodiments of the present disclosure and the apparatuses according to embodiments of the present disclosure charge control is provided. The packaging substrate can be discharged or charged to defined conditions. A repeatable voltage contrast signal by SEs (signal electron) and an improved defect detection success rate (S/N-ratio, signal noise ratio) on several substrates and after repeated e-beam scans and test sequences can be provided by discharging the test substrate to a defined starting condition in regards of potential and charge distribution. According to embodiments of the present disclosure, to control the charge condition of an AP or PLP substrate an ion source is utilized. A defined oriented electric field is provided. The electric field separates positive ions from negative ions and guides the positive ions towards the substrate. According to some embodiments, which can be combined with other embodiments described herein, the ion source and the electric field electrodes can be integrated within the vacuum test chamber. The positive ions any residual negative charge on the substrate, which is advantageous for the following e-beam test signal to noise ratio. In addition,—the positive ions may provide a positive potential bias to the test substrates, which may be advantageous for the following e-beam test.

According to an embodiment, a method for testing a packaging substrate with at least one electron beam column is provided. The packaging substrate is a panel level packaging substrate or an advanced packaging substrate. The method includes placing the packaging substrate on a stage in a vacuum chamber; flooding at least portions of the vacuum chamber with positive ions; generating an electric field between one or more electrodes and the packaging substrate, the electric field being configured to accelerate the positive ions towards the substrate; testing the packaging substrate in the vacuum chamber.

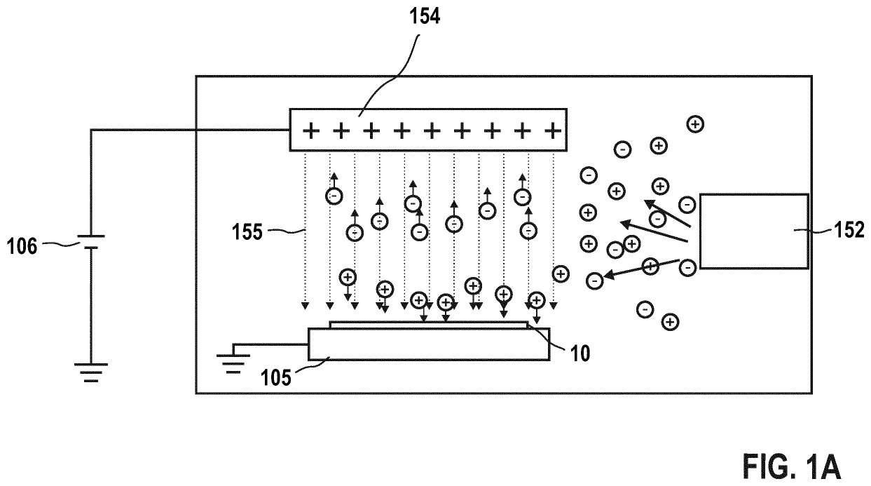

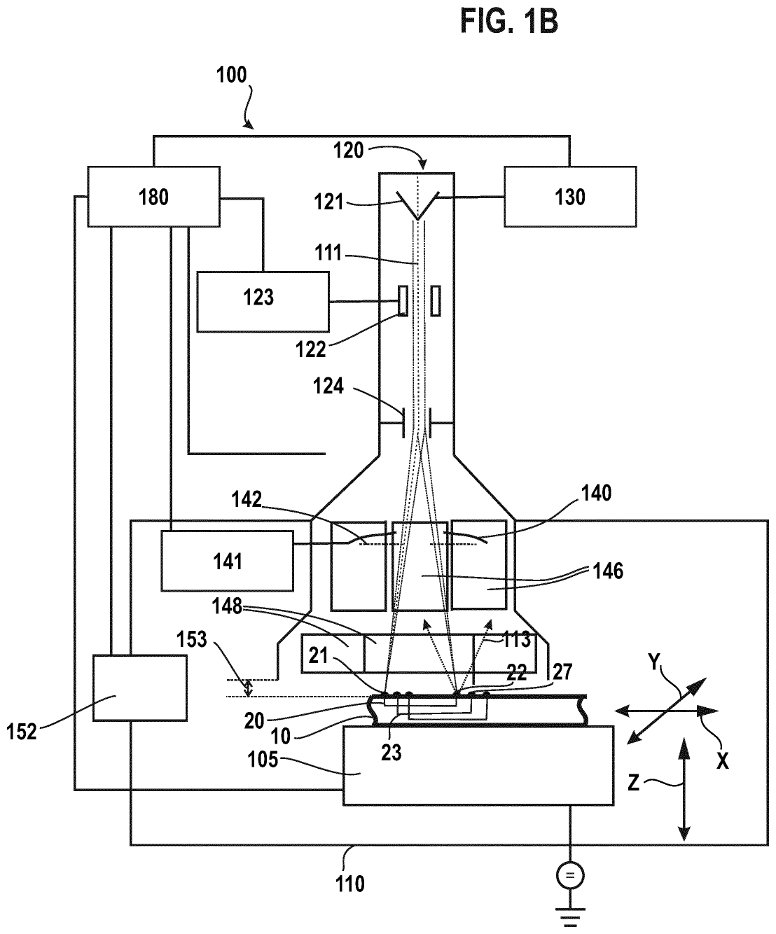

FIG. 1A shows a schematic view of an apparatus illustrating the concept of charge control. A packaging substrate 10 is supported on a stage 105. The packaging substrate is supported in the vacuum chamber 110. According to some embodiments, which can be combined with other embodiments described herein, one or more ion sources are located within the vacuum chamber 110 or at least partially within the vacuum chamber. FIG. 1A shows an ion source 152. The ion source 152 generates positive ions and negative charges. The vacuum chamber or at least portions thereof are flooded with the positive ions and the negative charges. According to embodiments of the present disclosure, the negative charges may be electrons or negative ions. In the following acceleration of positive ions towards the substrate is described. However, by changing the potentials of the components, which are exemplarily shown in FIG. 1A, also negative ions or electrons may be accelerated towards the substrate.

An electrode 154 generates an electric field 155. As shown in FIG. 1A, the electric field 155 accelerates the positive ions towards the packaging substrate 10. Accordingly, a positive charge is provided on the packaging substrate 10. For an electrode 154, which is on a negative potential relative to the substrate, negative ions or electrons are accelerated towards the packaging substrate. Accordingly, a negative charged can be provided on the packaging substrate.

According to some embodiments, which can be combined with other embodiments described herein, an ion source 152 can be selected from an ion source with gas supply, a UV source, such as a VUV source, a spark generation unit, or another ion generating unit. For example, a VUV source generating ions may ionizes a residual gas in the vacuum chamber, wherein, for example, the ion density can be controlled by the base pressure and free path of the ion generic trajectories. According to some embodiments, which can be combined with other embodiments described herein, a flooding of the vacuum chamber with positive ions and/or negative charges is provided by an ion source at least partially provided in the vacuum chamber.

As shown in FIG. 1B, the ions are released from the ion source 152 and distributed within the vacuum chamber 110. Particularly, the ions can be distributed between the stage 105 and the electrode 154. The electric field 155 separates the positive ions and the negative ions, or electrons, respectively. According to some embodiments, which can be combined with other embodiments described herein, the packaging substrate 10 can be placed on the stage 105 being on the ground potential and a positively charged electrode 154. The voltage between the electrode 154 and the stage can be provided by a power supply 106. As shown in FIG. 1B, the electrode 154 can be a separate element provided in a testing apparatus or can be integrated in a charged particle beam column as shown in FIG. 1B.

According to embodiments mainly described in the present disclosure, the positive ions are forced toward the substrate while the negative ions or electrons are accelerated towards the positively charge electrode 154. A self-aligning process is provided, which leads to a uniform charge distribution. For example, if a first area of the packaging substrate 10 is charged more positive as compared to a second area of the packaging substrate 10, the first area will be subject to smaller electric field and, thus, to a reduced positive charge during subsequence charge control operation. The deposition of ions on the substrate will stop when the ions compensate the applied electrical field by the electrodes in any area of the substrate within the homogeneous electrical field.

Accordingly, by controlling the strength of the electric field, the substrate can be charged to a defined potential. For example, an electrode 154, which would be charged to +100V would result in a zero electric field upon charges accumulated on the substrate 10, such that the substrate is also bias to +100 V. Accordingly, the substrate potential can be adjusted to a predefined value.

According to some embodiments, which can be combined with other embodiments described herein, a residual positive or negative charge on or in the loaded test substrate can be neutralized by the negative charge or the positive ions before testing of the packaging substrate, for example, with a charged particle beam column directing an electron-beam on portions of the packaging substrate. Yet further it is optionally possible, that test substrate can be charged to a more positive potential or to a more negative potential. Particularly, it is according to embodiments, which can be combined with other embodiments described herein to charge the substrate to a defined potential, e.g. a defined potential relative to ground. For a following e-beam test, higher voltage contrast between the positive substrate and a negatively charged test structures on the sample may advantageously be provided.

According to embodiments of the present disclosure, embodiments of the present disclosure set the packaging substrate to a defined and, for example, homogeneous starting condition (charge distribution) for better defect detectability and repeatability. Accordingly, an improved signal to noise ratio for the e-beam measurements can be provided due to defined starting condition, particularly the defined starting conditions of all test points.

As described with respect to FIG. 1B and FIGS. 5 and 6, a method for testing a packaging substrate is provided. The packaging substrate is a panel level packaging substrate or an advanced packaging substrate. The method being conducted with at least one electron beam column includes placing the packaging substrate on a stage in a vacuum chamber.

According to some embodiments, which can be combined with other embodiments described herein, the at least one electron beam is directed on the at least first portion with a first landing energy and on the at least second portion with a second landing energy different than the first charging landing energy. For example, the signal electrons can be detected upon impingement of the at least one electron beam with the second energy for reading of a charge on the packaging substrate. A charge control is provided by generating positive ions or negative charges to e.g. neutralize negative charge on a packaging substrate before testing, between test sequences, and/or after testing.

The complexity of packaging substrates has been increasing for years, with the aim of reducing the space requirements of semiconductor packages. For reducing the manufacturing costs, packaging techniques were proposed, such as 2.5D ICs, 3D-ICs, and wafer-level packaging (WLP), e.g. fan-out WLP. In WLP techniques, the integrated circuit is packaged before dicing. A “packaging substrate” as used herein relates to a packaging substrate configured for an advanced packaging technique, particularly an WLP-technique or a panel-level-packing (PLP)-technique.

“2.5D integrated circuits” (2.5D ICs) and “3D integrated circuits” (3D ICs) combine multiple dies in a single integrated package. Here, two or more dies are placed on a packaging substrate, e.g. on a silicon interposer or a panel-level-packaging substrate. In 2.5D ICs, the dies are placed on the packaging substrate side-by-side, whereas in 3D ICs at least some of the dies are placed on top of each other. The assembly can be packaged as a single component, which reduced costs and size as compared to a conventional 2D circuit board assembly.

A packaging substrate typically includes a plurality of device-to-device electrical interconnect paths for providing electrical connections between the chips or dies that are to be placed on the packaging substrate. The device-to-device electrical interconnect paths may extend through a body of the packaging substrate in a complex connection network, vertically (perpendicular to the surface of the packaging substrate) and/or horizontally (parallel to the surface of the packaging substrate) with end points (referred to herein as surface contact points) exposed at the surface of the packing substrate.

An advanced packaging (AP) substrate provides the device-to-device electrical interconnection paths on or within a wafer, such as a silicon wafer. For example, an AP substrate may include Through Silicon Vias (TSVs), e.g., provided in a silicon interposer, other conductor lines extending through the AP substrate. A panel-level-packaging substrate is provided from a compound material, for example material of a printed circuit board (PCB) or another compound material, including, for example ceramics and glass materials.

Panel-level-packaging substrates are manufactured that are configured for the integration of a plurality devices (e.g., chips/dies that may be heterogeneous, e.g. may have different sizes and configurations) in a single integrated package. Further, AP substrates may be combined on a PLP substrate. A panel-level substrate typically provides sites for a plurality of chips, dies, or AP substrates to be placed on a surface thereof, e.g. on one side thereof or on both sides thereof, as well as a plurality of device-to-device electrical interconnect paths extending through a body of the PLP substrate.

Notably, the size of a panel-level-substrate is not limited to the size of a wafer. For example, a panel-level-substrate may be rectangular or have another shape. Specifically, a panel-level-substrate may provide a surface area larger than the surface area of a typical wafer, e.g., 1000 cm² or more. For example, the panel-level substrate may have a size of 30 cm×30 cm or larger, 60 cm×30 cm or larger, 60 cm×60 cm or larger.

According to embodiments of the present disclosure, E-beam testing and/or E-beam review provides for testing of contact pads of 60 μm or below or even about 10 μm or below. Voltage contrast testing imaging can be provided. Testing can be provided at or between “surface contact points” of the packaging substrate.

A “surface contact point” may be understood as an end point of an electrical interconnect path that is exposed at a surface of the packaging substrate, such that an electron beam can be directed on the surface contact point for contactless charging or probing the electrical interconnect path. A surface contact point is configured to electrically contact a chip, a die, a smaller package, or other electrical components like capacitors, resistors, coils, or the like, that is to be placed on the surface of the packaging substrate, e.g. via soldering. Electrical components may also include active electrical components, such as transformer changing the voltage in a region of the package. In some embodiments, the surface contact points may be or may include solder bumps.

According to embodiments of the present disclosure, 100% of the electrical interconnect paths are tested. The costs of ownership of device packages including the chips etc., such as processors, memories, or the like (microelectronic devices), is mainly determined by the highly integrated microelectronic devices. Accordingly, mounting a non-defective microelectronic device to a defective packaging substrate is disadvantageous with respect to manufacturing cost. A fully non-defective packaging substrate is desirable before mounting of the microelectronic devices.

The present disclosure relates to methods and apparatuses for testing packaging substrates that are configured for the integration of a plurality of devices in one integrated package, and that include at least one device-to-device electrical interconnect path. According to embodiments of the present disclosure, a test system, test apparatus, or test method may detect and/or classify defective electrical connections in a packaging substrate, such as opens, shorts, leakage defects, or others. Particularly, the test methods and test systems may provide a contactless testing. A contact pad pitch of 60 μm or below or even about 10 μm or below is difficult and even impossible for mechanical probing. Also, the small contact pads must not be damaged by any scratch. Contactless testing is beneficial.

According to some embodiments, which can be combined with other embodiments described herein, a further charge control during writing of a charge can be provided by operating the electron beam column with a defined landing energy. Particularly, the landing energy, i.e. the energy of the electron beam upon impingement of the packaging substrate, can be varied to control the charge provided on the packaging substrate. By variation of the landing energy, an area of impingement of the electron beam can be charged positively, negatively, or not charged. During a writing operation, no charge is beneficially provided to the packaging substrate. A contactless electrical test can be provided with an e-beam, wherein the charge can be at, for example, a first surface contact point, and charge can be read at, for example, a second surface contact point. This enables the detection and classification of electrical defects of the packaging substrate. The different e-beam landing energies (Upe) control the SE yield (secondary electron yield) and, thus, the total electron yield. To achieve voltage contrast signal on several substrates and/or after repeated e-beam scans and test sequences with a good repeatability, it is beneficial to discharge the test substrate to a defined condition, for example, the starting condition in regards of potential and charge distribution.

According to some embodiments, which can be combined with other embodiments described herein, a method for testing of packaging includes placing the packaging substrate on a stage in a vacuum chamber; directing an electron-beam of the at least one electron beam column with the first landing energy on at least a first portion of the packaging substrate and directing the electron-beam of the at least one electron beam column with a second landing energy different than the first landing energy on the packaging substrate. The method further includes detecting signal electrons emitted upon impingement of the electron-beam for testing at least the first device-two-device electrical interconnect path of the packaging substrate.

Testing of features, for example, electrical interconnection path, of the packaging substrate can be provided, wherein charge up of features and/or the packaging substrate can be controlled. Variation of the e-beam primary energy (Upe), i.e. the landing energy of the electron beam on the packaging substrate can be utilized control the charge on the packaging substrate or respective portions thereof. The test may include a voltage signal reading, i.e. a voltage contrast measurement upon detection of signal electrons, for example, secondary electrons. Test positions, i.e. surface contact points, of an advanced packaging substrate or panel level packaging substrate can be charged without contact to avoid damage to the surface contact points.

FIG. 1B shows an apparatus 100 for testing a packaging substrate 10 according to embodiments described herein in a schematic sectional view. The apparatus 100 includes a vacuum chamber 101 that may be a testing chamber specifically configured for testing or that may be one vacuum chamber of a larger vacuum system, e.g. a processing chamber of a packaging substrate manufacturing or processing system.

As it is schematically depicted in FIG. 1B, a packaging substrate 10 includes a first device-to-device electrical interconnect path 20 extending between a first surface contact point 21 and a second surface contact point 22 of the packaging substrate 10. Optionally, the first device-to-device electrical interconnect path 20 may extend between three or more surface contact points that may be provided on the same surface or on two opposite surfaces of the packaging substrate. The device-to-device electrical interconnect path 20 depicted in FIG. 1B extends only between the first surface contact point 21 and the second surface contact point 22 that are both arranged at a top surface of the packaging substrate, but the present disclosure is not limited to such device-to-device electrical interconnect paths, and the device-to-device electrical interconnect path may be a complex network of vias, pillars, and/or conductor lines extending through the packaging substrate and having a plurality of surface contact points.

The packaging substrate 10 may include a plurality of device-to-device electrical interconnect paths 20 for connecting a plurality of devices that are to be placed on the packaging substrate 10. In FIG. 1B, three device-to-device electrical interconnect paths are exemplarily depicted, but the packaging substrate 10 may include thousands or ten-thousands of such device-to-device electrical interconnect paths that are typically electrically isolated from each other, if no short exists between two electrical interconnect paths.

According to embodiments described herein, the packaging substrate 10 is placed on a stage 105 in the vacuum chamber 101. The stage can be movable, particularly in the z-direction (i.e., in a direction perpendicular to the stage surface) and/or in the x- and y-directions (i.e., in the plane of the stage surface). The stage 105 is provided within the vacuum chamber and is configured to support the packaging substrate being one of a panel level packaging substrate and an advanced packaging substrate. An electron beam 111 is directed on the first surface contact point 21. The electron beam can be scanned to be directed to that second surface contact point 22. Signal electrons 113 emitted from the second surface contact point 22 are detected for testing the first device-to-device electrical interconnect path 20. The signal electrons may be secondary electrons and/or backscattered electrons. For example, it can be determined whether the first device-to-device electrical interconnect path 20 has an “open”-defect.

Alternatively or additionally, the electron beam 111 is directed on a further surface contact point 27 that is not an end point of the first device-to-device electrical interconnect path 20, i.e. that belongs to a second device-to-device electrical interconnect path 23 that may extend through the packaging substrate adjacent to the first device-to-device electrical interconnect path 20. Signal electrons emitted from the further surface contact point 27 are detected for testing the first device-to-device electrical interconnect path 20. The signal electrons may be secondary electrons and/or backscattered electrons. For example, it can be determined whether the first device-to-device electrical interconnect path 20 has a “short”-defect.

In particular, by detecting the signal electrons 113 emitted upon impingement of the electron beam 111 on the packaging substrate (particularly, by determining the energy of the signal electrons 113 that depends on the electric potential of the second surface contact point 22 or of the further surface contact point 27), it can be determined in a “voltage contrast measurement”, if the first device-to-device electrical interconnect path 20 is defective. Specifically, defective connections in the packaging substrate can be determined and classified, e.g. in open, short and/or leakage defects.

In some embodiments, which can be combined with other embodiments described herein, one or more electrical connections extending between surface contacts on different sides of the substrate are inspected. In yet further embodiments, a first plurality of electrical connections extending between surface contacts on a first side of the substrate, a second plurality of electrical connections extending between surface contacts on a second side of the substrate, and/or or third plurality of electrical connections extending between surface contacts on different sides of the substrate are inspected. For example, one or more electron beam columns may be arranged on both sides of the substrates (not shown in the figures), such that surface contacts on both sides of the substrate can be charged and/or discharged for inspecting and testing the respective electrical connections.

According to embodiments described herein, both the charging and the probing is provided with an electron beam, particularly a scanning electron beam. Other testing methods like electrical and/or mechanical probing cannot provide the throughput provided by the methods and systems described herein. The methods and system described herein rely on the contactless charging and probing with electron beams. Further, the contact reliability of an electrical and/or mechanical tester decreases with the decreasing size and the increasing density and number of surface contact points that are to be tested in advanced packaging substrates. For example, contact pad sizes of 30 μm or less are difficult for mechanical probing. Further, the topography of the packaging substrates and of the surface contact points of packaging substrates may pose a problem for other test methods, such as for capacitive detectors or electric field detectors. It is further advantageous to have a charging electron beam, e.g. as compared to a flood gun electron charging. In light of the complexity of the packing substrates, the capability of local charging as compared to charging an entire area with a flood gun improves the test procedures that are available. Further, local charging reduces the overall charge accumulated on the packing substrate. Yet further, different charging in different areas may result in a reduced overall charge provided on the substrate. For example, the overall charged can be kept close to neutral if one area is charged positive and another area is charged negative. According to some embodiments, which can be combined with other embodiments described herein, a pattern of different charges can be provided on portions of the packaging substrate.

The testing method described herein is suitable for testing packaging substrates for multi-device in-package integration, particularly for testing panel-level-packaging substrates (PLP substrates) or advanced packaging substrates (AP substrates), and uses an e-beam both for charging the device-to-device electrical interconnect path 20 and for reading the charged circuitry voltage, particularly by probing the second surface contact point and/or further surface contact points. In other words, both the “electrical driving” and the “probing” is done with an electron beam, such that defects can be reliably and quickly found. Testing by e-beam charging and e-beam probing (e.g., with an EBT column or an EBR column) is independent of topography, fast, and flexible in regards of contact point positions, size and geometry, whereas the topography of the packaging substrate may be a problem for other test methods like capacitive or electric field detectors.

A packing substrate, such as a PLP substrate, may include a plurality of device-to-device connections, e.g. 5.000 or more, 10.000 or more, 20.000 or more, or even 50.000 or more. The connections may include Through Silicon Vias (TSVs), e.g., provided in a silicon interposer, other conductor lines extending through the packaging substrate, and/or may include multi-die interconnect bridges that may be embedded in the packaging substrate. The packaging substrate may be a multi-layer substrate including electrical interconnections in a plurality of layers arranged on top of each other, e.g. in a layer stack.

In some embodiments, the packaging substrate 10 includes a plurality of device-to-device electrical interconnect paths extending between respective first and second surface contact points, and optional further contact points, and the method may include testing the plurality of device-to-device electrical interconnect paths sequentially or in parallel. “Sequential testing” as used herein refers to the subsequent testing of a plurality of device-to-device electrical interconnect paths of the packaging substrate. For example, 5.000 or more device-to-device electrical interconnect paths are tested one after the other. “Parallel testing” as used herein may refer to the synchronous testing of two or more device-to-device electrical interconnect paths. “Parallel testing” as used herein may also refer to the testing of several device-to-device electrical interconnect paths by scanning the electron beam for charging within one field of view over several first surface contact points while scanning the electron beam for probing in one field of view over several corresponding second surface contact points.

In some embodiments, directing the electron beam 111 on the first surface contact point includes focusing the electron beam 111 on the first surface contact point 21, e.g. with a beam probe diameter on the packaging substrate of 30 μm or less, particularly 10 μm or less. A focusing of the charging electron beam on the packaging substrate, e.g. with an objective lens, can prevent the charging of substrate surface areas different from the surface contact points and can provide more accurate testing results. Additionally or alternatively, particularly for detection of signal electron beams, the electron beam may be scanned across a portion of the packaging substrate to generate an image of a portion of the packaging substrate. The image can include voltage contrast information. A defect detection of one or more electrical interconnect paths or a classification of the defect can be provided, for example, by pattern recognition within the image.

While conventional PCBs typically include comparatively large flat metal pads that form surface contact points for testing, a packaging substrate that is tested according to embodiments described herein may include huge numbers of small, convexly shaped solder bumps to be tested which makes testing more challenging. In particular, the first surface contact point 21 and the second surface contact point 22 may have a maximum dimension of 25 μm or less, particularly 10 μm or less, respectively. For example, the first and second surface contact points may be essentially round, particularly semi-spherically shaped, with a diameter of 25 μm or less, particularly 10 μm or less. According to some embodiments, which can be combined with other embodiments described herein, a surface contact point can have a three-dimensional topography, particularly a substantially semi-spherical shape.

In contrast to mechanical testers, electron beams can be accurately directed on such small surface areas because electron beams can be focused down to very small probe diameters and can be accurately directed on predetermined points of the substrate, e.g. with scan deflectors, e.g. with an accuracy in a sub-μm-range. While other testers may slip or slide from surface contact points with a convex geometry, electron beams can be accurately focused onto arbitrary geometries, such that the testing methods described herein are geometry-independent and topography-independent.

As it is schematically depicted in FIG. 1B, the charged particle beam column 120 may be provided on a first side of the stage 105. In some embodiments, which can be combined with other embodiments described herein, the charged particle beam column 120 may have an electron source 121 for generating an electron beam as well as beam-optical elements, such as a scan deflector 122 and/or an objective lens 124, for directing the first electron beam onto a substrate placed on the stage 105. The objective lens 124 may be an electrostatic objective lens (as shown in FIG. 1B), a magnetic objective lens, or a magnetic-electrostatic objective lens.

The apparatus 100 further includes an electron detector 140 for detecting signal electrons 113 emitted upon impingement of the second electron beam on the packaging substrate, and an analysis unit 141 configured to determine, based on the signal electrons 113, if the first device-to-device electrical interconnect path 20 is defective. In some embodiments, the analysis unit 141 may be configured to determine, based on the detected signal electrons, whether an electrical interconnect path has a defect, such as a short, an open and/or a leakage. Optionally, the analysis unit 141 may be configured to classify any detected defect. In some embodiments, the analysis unit 141 may be configured to determine, based on the detected signal electrons from subsequent measurements, whether a short or a leakage exists between two or more electrical interconnect paths. In some implementations, the signal electrons 113 detected by the electron detector 140 may provide information about an electric potential of the substrate location from which the signal electrons 113 are emitted or reflected, and the analysis unit 141 may be configured to determine from said information if the first device-to-device electrical interconnect path 20 is defective or not. The analysis unit 141 may be further configured to classify a determined defect. Specifically, testing may include determining, by the analysis unit 141, if the first device-to-device electrical interconnect path 20 has any of a short, an open, and/or a leakage. An “open” is understood as an open electrical interconnect path that does not actually electrically connect the first surface contact point 21 and the second surface contact point 22. A “short” is understood as an electrical connection between two electrical interconnect paths that are actually to be electrically separated.

The charged particle beam column 120 as shown in FIG. 1B includes the first plurality of electrodes 146 and a second plurality of electrodes 148. The first plurality of electrodes 146 can generate a multi-pole field, for example, an octupole field, to guide the signal electrons 113 towards the electron detector 140. For example, the first plurality of electrodes can include eight or more electrodes for generating an octupole field. Particularly, the multi-pole field generated by the first plurality of electrodes 146 can be dynamically adjusted to the position of the electron beam 111 on the packaging substrate 10. The second plurality of electrodes 148 can generate a multi-pole field, for example, an octupole field, to guide the signal electrons 113 towards the electron detector 140. For example, the second plurality of electrodes can include eight or more electrodes for generating an octupole field. Particularly, the multi-pole field generated by the second plurality of electrodes 146 can be static. According to some embodiments, which can be combined with other embodiments described herein, one or more electrodes in the charged particle beam column 120 can be at least one assembly of four or eight electrodes (or more electrodes) configured to generate a multipole field for guiding signal electrons.

FIG. 1B further shows an ion source 152 and a gap 153. The ion source 152 generates, for example, positive ions as exemplarily illustrated in FIG. 1A. The gap 153 allows the positive ions to be distributed above the packaging substrate 10. During charge control operation of the apparatus 100 the first plurality of electrodes 146 and/or the second plurality of electrodes 148 can be charged to generate an electric field configured to accelerate positive ions or negative charges towards the substrate. The first plurality of electrodes 146 and/or the second plurality of electrodes 148 can be biased to generate a uniform electric field, particularly at or adjacent the upper surface of the packaging substrate 10.

According to an embodiment, an apparatus for contactless testing of a packaging substrate is provided. The apparatus includes a vacuum chamber 101 and a stage 105 within the vacuum chamber. The stage is configured to support a packaging substrate 10, wherein the packaging substrate is a panel packaging substrate or an advanced packaging substrate. The apparatus further includes a charged particle beam column 120 configured to generate an electron beam. The charged particle beam column includes an objective lens 124 configured to focus the electron beam on the packaging substrate, a scanner configured to scan the electron beam to different positions on the packaging substrate and an electron detector 140 for detecting signal electrons 113 emitted upon impingement of the electron beam on the packaging substrate. The apparatus further includes one or more electrodes configured to generate an electric field between one or more electrodes and the packaging substrate, the electric field being configured to accelerate the positive ions or negative charges towards the substrate. Further, an analysis unit 141 is provided. The analysis unit determines, based on the signal electrons 113, if a first device-to-device electrical interconnect path 20 is defective.

According to some embodiments, which can be combined with other embodiments described herein, and as shown in FIG. 1B, the one or more electrodes can be provided in the charged particle beam column. For example, the one or more electrodes can be positioned to guide signal electrons towards the detector. According to some embodiments, which can be combined with other embodiments described herein, a gap is provided between the one or more electrodes and the packaging substrate. Particularly, the gap can be provided between the at least one electron beam column and the packaging substrate.

According to some embodiments, which can be combined with other embodiments described herein, the electric field as exemplarily shown in FIG. 1A and the electric field generated by the first plurality of electrodes and/or the second plurality of electrodes can be uniform, particularly at a surface of the packaging substrate. The electric field can also be uniform between the surface of the packaging substrate and the one or more electrodes. An electric field being uniform within a region is constant at every point in this region. A uniform electric field has the same strength and the same direction at each point and is be compatible with homogeneity, i.e. all points experience the same physics. Accordingly, a uniform electric field may also be referred to as a homogeneous electric field.

The first plurality of electrodes and/or the second plurality of electrodes can be utilized for guiding of signal electrons during detection of the signal electrons and can be utilized for generating the electric field for charge control. According to additional or alternative modifications, the electric field may be generated by a further electrode, for example, electrode 154 shown in FIG. 1A, or by a combination of a further electrode and the first plurality of electrodes and/or the second plurality of electrodes.

In some embodiments, which can be combined with other embodiments described herein, the electron detector 140 includes an Everhard-Thornley detector. An energy filter 142 for the signal electrons 113 may be arranged in front of the electron detector 140, particularly in front of the Everhard-Thornley detector, as schematically depicted in FIG. 1B. The energy filter may include a grid electrode configured to be set on a predetermined potential. The energy filter 142 may allow the suppression of low-energy signal electrons. The energy filter 142 may suppress signal electrons that are irrelevant for the voltage contrast measurements to be conducted. In some implementations, the energy filter 142 may suppress signal electrons emitted from uncharged surface areas and may only let through signal electrons emitted from a charged surface contact point. Accordingly, the signal current detected by the electron detector may depend on the energy of the signal electrons which indicates if a probed surface contact point is defective or not.

In some embodiments, the apparatus 100 may include a scan controller 123 connected to a scan deflector 122 of the charged particle beam column 120. The scan deflector 122 may be configured to scan the electron beam over a substrate surface. The electron beam may be directed on a portion of the packaging substrate, e.g. with a first beam probe diameter. The portion of the packaging substrate can be an area of the packaging substrate, wherein the electron beam is scanned or the area of the packaging substrate. The electron beam can be raster scanned over the portion of the packaging substrate. For example, one or more scan deflectors 122 can scan the electron-beam over the portion of the packaging substrate. The portion of the packaging substrate may also be a surface contact point. The electron-beam can be vector scanned to one or more surface contact points of the packaging substrate. For example, one or more scan deflectors can be used to wake her scan the electron-beam to one or more surface contact points.

For example, the scan controller 123 may be configured to control the scan deflectors such that the electron beam is sequentially directed to pairs of first and second surface contact points for testing respective device-to-device electrical interconnect paths extending between the respective pairs of first and second surface contact points. This allows a quick and reliable test of a plurality of electrical interconnect paths extending through the packaging substrate.

According to some embodiments, which can be combined with other embodiments described herein, the electron beam can be vector scanned to individual positions, for example surface contact points of the packaging substrate, for charging and can be vector scanned to individual positions for detecting signal electrons. Alternatively, the electron beam can be vector scanned to individual positions, for example surface contact points of the packaging substrate, for charging and can be raster scanned or an area of the packaging substrate for detecting signal electrons. According to some embodiments, which can be combined with other embodiments described herein, an electron-beam of the charged particle beam column can be scanned to one or more positions on the packaging substrate for charging and for detecting of signal electrons.

As it is schematically depicted in FIG. 1B, the electron source 121 is connected to a power supply 130. The power supply can provide a high-voltage to the electron source for emitting the electron beam, i.e. the primary electron beam, from the electron source. According to some embodiments, which can be combined with other embodiments described herein, the voltage provided by the power supply 130 can be varied to change the energy of the electron beam and, thus, the landing energy of the electron beam on the packaging substrate. According to some embodiments, which can be combined other embodiments described herein, one or more power supplies can be connected to various components of the electron beam column. For example, power supplies can be connected to the electron source (as shown in FIG. 1B), to an extractor of the electron source, to an anode of the electron source, to a deceleration electrode configured to decelerate the electrons before impingement on the packaging substrate, and/or to the stage 105. The landing energy of the electron beam on the packaging substrate is determined by the potential difference between the potential of the emitter tip of the electron source and the potential of the packaging substrate or the potential of the stage 105, respectively. Accordingly, one or more power supplies to vary the landing energy of the electron beam can be provided.

According to an embodiment, an apparatus for contactless testing of a packaging substrate is provided. The packaging substrate is a panel packaging substrate or an advanced packaging substrate. The apparatus includes a vacuum chamber 101 and a stage 105 within the vacuum chamber, wherein the stage is configured to support the packaging substrate being a panel packaging substrate or an advanced packaging substrate. The apparatus further includes an electron beam column configured to generate an electron beam, wherein the electron beam column includes an objective lens configured to focus the electron beam on the packaging substrate, a scanner configured to scan the electron beam to different positions on the packaging substrate, and an electron detector for detecting signal electrons emitted upon impingement of the electron beam on the packaging substrate. The apparatus further includes one or more electrodes configured to generate an electric field between one or more electrodes and the packaging substrate, the electric field being configured to accelerate the positive ions or negative charges towards the substrate.

FIG. 1B exemplarily illustrates the stage 105 being connected to ground. The stage may be connected directly to ground, may be connected to ground via a DC power supply as exemplarily shown in FIG. 1B, or may be connected to ground via an AC power supply. According to some embodiments, which can be combined with other embodiments described herein, the stage can include a conductive stage surface connected directly or indirectly to ground for providing a reference potential.

When placing the packaging substrate on the stage 105, the packaging substrate has a defined charge provided thereon. Irrespective thereof, the stage can be conductive. Accordingly, the stage can be provided at a defined potential. For example, the defined potential may be ground potential or may be a potential negative or positive with respect to ground. For example, a DC power supply can be provided between ground and a conductive stage. Alternatively, an AC power supply can be provided between ground and a conductive stage, wherein an alternating defined potential can be provided. According to some embodiments, which can be combined with other embodiments described herein, the surface of the stage 105 is provided with a non-conductive material. For example, a layer of dielectric material can be provided as the surface of the stage. Having a non-conductive stage surface allows charge is applied to the packaging substrate to maintain on the packaging substrate in order to be detected during the testing operation or a defect review operation.

According to some embodiments, which can be combined with other embodiments described herein, the stage includes a conductive stage surface connected directly or indirectly to ground for providing a reference potential. According to yet further additional or alternative modifications, the packaging substrate can be partially connected to ground, for example, by the stage. For example, some circuitries can be connected to GND while some circuits are not connected to ground. According to yet further modifications, which can be combined with other embodiments described herein, the packaging substrate can be capacitively connected to ground, e.g. by the stage. For some embodiments, there is no ohmic connection.

The defined potential of the stage, particularly a conductive stage, provides electric field lines, particularly at non-conductive portions of the stage surface and the packaging substrate. The defined potential can be utilized to influence the electron-beam of the electron-beam column.

According to yet further embodiments, which can be combined with other embodiments described herein, a capacitive coupling of the packaging substrate to the stage 105 can provide the packaging substrate on a defined potential. For example, a capacitive coupling to ground can be provided by the conductive stage 105 to ground. Additionally or alternatively a predetermined set of structures on the packaging substrate may be connected to ground. However, predetermined set of structures may not be charged due to the grounding and may serve as a reference potential.

FIG. 1B shows a controller 180. According to some embodiments, which can be combined with other embodiments described herein, the controller can be connected to one or more of the components of the apparatus 100 for contactless testing of a packaging substrate and for charge control. As exemplarily shown in FIG. 1B, the controller can be connected to the power supply 130, the scan controller 123, the analysis unit 141, the ion source 152, and the stage 150. The controller may also be connected to the electron detector 140.

The controller 180 comprises a central processing unit (CPU), a memory and, for example, support circuits. To facilitate control of the apparatus for testing packaging substrates, the CPU may be one of any form of general purpose computer processor that can be used in an industrial setting for controlling various chambers and sub-processors. The memory is coupled to the CPU. The memory, or a computer readable medium, may be one or more readily available memory devices such as random access memory, read only memory, hard disk, or any other form of digital storage either local or remote. The support circuits may be coupled to the CPU for supporting the processor in a conventional manner. These circuits include cache, power supplies, clock circuits, input/output circuitry and related subsystems, and the like. Inspecting process instructions are generally stored in the memory as a software routine typically known as a recipe. The software routine may also be stored and/or executed by a second CPU (not shown) that is remotely located from the hardware being controlled by the CPU. The software routine, when executed by CPU, transforms the general purpose computer into a specific purpose computer (controller) that controls the apparatus operation such as that for controlling the charge control, landing energy, the stage positioning and/or charged particle beam scanning during the testing operation. Although the method and/or process of the present disclosure is discussed as being implemented as a software routine, some of the method steps that are disclosed therein may be performed in hardware as well as by the software controller. As such, embodiments of the invention may be implemented in software as executed upon a computer system, and hardware as an application specific integrated circuit or other type of hardware implementation, or a combination of software and hardware.

The controller may execute or perform a method of testing a packaging substrate with an electron beam column. The method according to some embodiments includes generating ions and generating an electric field for charge control with the ions. Further, the method includes testing of packing substrates, particularly by directing an electron-beam of the at least one electron beam column on at least a first portion of the packaging substrate and directing the electron beam of the at least one electron beam column on the packaging substrate. The method further includes detecting signal electrons emitted upon impingement of the electron beam for testing at least one first device-to-device electrical interconnect path of the packaging substrate.

According to an embodiment, and apparatus for testing of packaging substrates with any of the methods described herein is provided. The apparatus may include the controller 180. The controller includes a processor and a memory storing instructions that, when executed by the processor, cause the apparatus to perform a method according embodiments of the present disclosure.

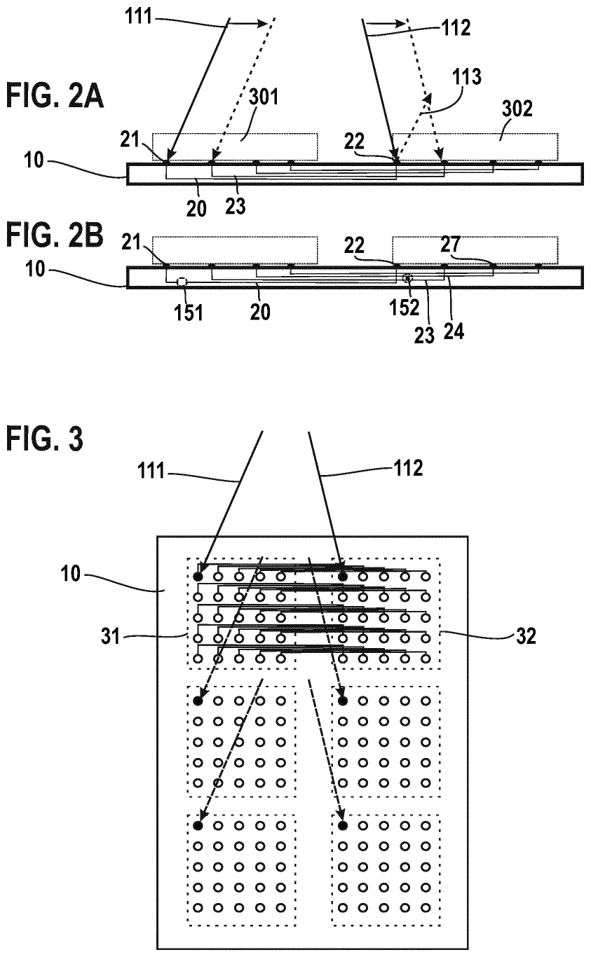

FIGS. 2A and 2B show enlarged sectional views of packaging substrates during a testing method described herein. The packaging substrate 10 may be an AP substrate or a PLP-substrate for the manufacture of a multi-die integrated package and includes a first die connection interface for attaching a first die 301 and a second die connection interface for attaching a second die 302. A plurality of device-to-device electrical interconnect paths (four of which are exemplarily shown in FIG. 2A and FIG. 2B) extend between a respective first surface contact point of the first die connection interface and a respective second surface contact point of the second die interconnection interface. The surface contact points may be formed as or include solder bumps that have a three-dimensional geometry, e.g., an essentially semi-spherical shape.

In FIG. 2A, a first device-to-device electrical interconnect path 20 extending between a first surface contact point 21 and a second surface contact point 22 is tested by directing a charging electron beam 111 on the first surface contact point 21 and directing the electron beam on the second surface contact point 22. Since the first surface contact point 21 is electrically connected to the second surface contact point 22 by the first device-to-device electrical interconnect path 20, the second surface contact point 22 should be at the same electrical potential as the first surface contact point 21 after charging of the first surface contact point 21. Signal electrons 113 emitted from the second surface contact point 22 are detected that carry an information about the electrical potential of the second surface contact point 22 which should be equal to the electrical potential of the first surface contact point 21. If an electrical potential of the second surface contact point 22 different from the electrical potential of the first surface contact point 21 is determined, a defect is detected. The detected voltage contrast can be used for characterizing the defect. Further, the detected voltage contrasts of subsequent measurements of neighboring electrical interconnect paths can be compared, in order to find out about shorts or leakages between different electrical interconnect path.

After the test of the first device-to-device electrical interconnect path 20, the electron beam 111 can be directed on two surface contact points of a second device-to-device electrical interconnect path 23, e.g. by scanning (vector scanning) the electron beams with respective scan deflectors to other positions and/or by moving the stage on which the packaging substrate is supported. A plurality of device-to-device electrical interconnect paths can be subsequently tested with the charging electron beam and the probing electron beam. Accordingly, a plurality of test points can be tested sequentially and/or in parallel.

In FIG. 2B, an open 151 exists in the first device-to-device electrical interconnect path 20. The open 151 is determined because the second surface contact point 22 is not charged after or during the charging of the first surface contact point 21 by the charging electron beam 111.

In FIG. 2B, a short 152 exists between the second device-to-device electrical interconnect path 23 and a third device-to-device electrical interconnect path 24. The short can be determined because the third device-to-device electrical interconnect path 24 is charged together with the second device-to-device electrical interconnect path 23, which can be detected by the probing electron beam that is directed on the further surface contact point 27 of the third device-to-device electrical interconnect path 24 after or during the charging of the second device-to-device electrical interconnect path 23.

For an evaluation and defect classification, the signals of measurements of neighboring interconnect paths and/or previously collected data can be compared, such that opens, shorts, and leakages in the packaging substrate can be identified.

FIG. 3 is a schematic top view of a packaging substrate 10 as described herein under test. The packaging substrate has a top surface with a plurality of surface contact points arranged in a 2-dimensional pattern. The packaging substrate 10 includes a first die connection interface 31 for attaching a first die, particularly by flip-chip mounting, a second die connection interface 32 for attaching a second die, particularly by flip-chip mounting, and optional further die connection interfaces that may be arranged pairwise next to each other. The first die connection interface 31 may include a plurality of first surface contact points, e.g., formed as solder bumps, and the second die connection interface 32 may include a plurality of second surface contact points, e.g., formed as solder bumps.

In some embodiments, each first surface contact point of the first die connection interface 31 is connected to one respective second surface contact point of the second die connection interface 32 by a device-to-device electrical interconnect path. For the sake of clarity, only the device-to-device electrical interconnect paths connecting the first and second die connection interfaces are depicted. According to some embodiments, which can be combined with other embodiments described herein, the first surface contact point may be connected to one second surface contact point. Alternatively, the first surface contact point may be connected to two or more second surface contact points. The two or more second surface contact points can be probed with the electron beam, for example, after charge has been applied to the first surface contact point.

According to the testing method described herein, the charging electron beam 111 is directed, particularly focused, on a first surface contact point of the first die connection interface 31, and the charging electron beam 111 is directed, particularly focused, on the associated second surface contact point of the second die connection interface 32. Signal electrons emitted from the second surface contact point are detected for testing whether an “open”-defect exists in the electrical interconnect path that connects the first and second surface contact points. Thereafter, the other surface contact points of the first and second die connection interfaces may be tested, particularly pairwise.

Alternatively or additionally, it can be tested in parallel or subsequently, whether the charging of one device-to-device electrical interconnect path leads to the charging of a surface contact point of another device-to-device electrical interconnect path, such that a “short”-defect can be determined. For example, the electron beam can be raster stand over a portion of the packaging substrate to generate an image of the portion of the packaging substrate. The image can be evaluated, for example, by pattern recognition.

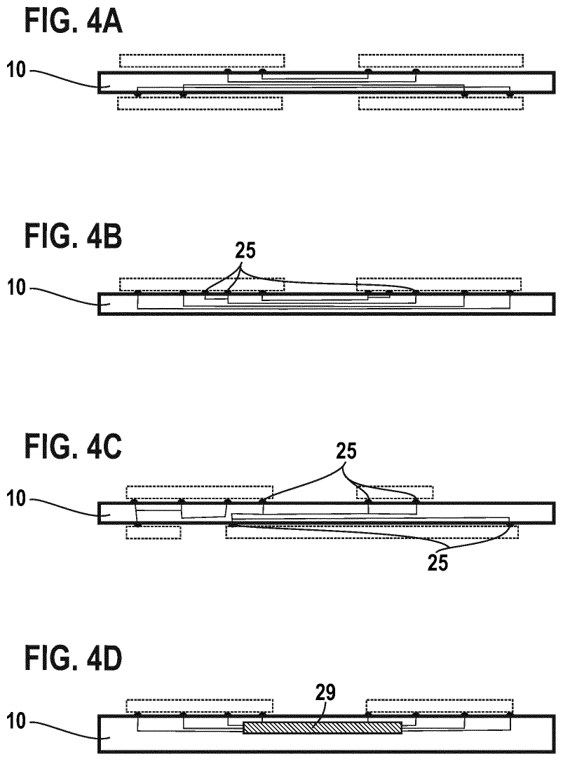

FIGS. 4A to 4D show enlarged sectional views of packaging substrates that can be tested according to the methods described herein.

The packaging substrate 10 depicted in FIG. 4A has surface contact points on both main surfaces of the packaging substrate. For example, a first plurality of device-to-device electrical interconnect paths may extend between first and second surface contact points exposed on an upper substrate surface, and a second plurality of device-to-device electrical interconnect paths may extend between first and second surface contact points exposed on a lower substrate surface

The packaging substrate 10 depicted in FIG. 4B has at least one device-to-device electrical interconnect path that extends between at least three surface contact points 25, i.e. a first surface contact point, a second surface contact point, and at least a third surface contact point.

The packaging substrate 10 depicted in FIG. 4C has at least one device-to-device electrical interconnect path that extends between at least three surface contact points 25 that are exposed on different main surfaces of the substrate in a complex connection network. Such a device-to-device electrical interconnect path may be configured for connecting three or more dies with each other through the packaging substrate.

The packaging substrate 10 depicted in FIG. 4D has at least one interconnect bridge 29 embedded in the packaging substrate 10. At least one device-to-device electrical interconnect path extends through the at least one interconnect bridge 29. In particular, a plurality of device-to-device electrical interconnect paths extending between a first die connection interface and a second die connection interface of the packaging substrate extend through the interconnect bridge. The interconnect bridge may be embedded in the packaging substrate during the manufacture of the packaging substrate. The interconnect bridge may be a bridge chip embedded in the packaging substrate for increasing the connection speed between multiple dies.

According to some embodiments, which can be combined with other embodiments described herein, test methods and/or apparatuses according to the present disclosure may be utilized during and/or after manufacturing of a packaging substrate. For example, a test may be applied on a packaging substrate that does not yet include all layers or structures. For example, a test may be conducted after a redistribution layer (RDL) has been manufactured and/or after a via layer has been manufactured. An RDL test and/or a via test can be provided. Yet further, a test may be provided on the finished packaging substrate.

A test may be provided by charging (writing on) one or more portions, e.g. surface contact points, and by detecting the charge by means of signal electrons (reading) a charge on the packaging substrate. The number of electrons emitted from the surface of the packaging substrate per irradiated electron, i.e. the total electron yield is energy dependent. For a total electron yield of 1, the same number of electrons reach the surface of the packaging substrate as compared to the number of signal electrons being emitted from or scattered at the surface of the packaging substrate. There are two neutral energy values, a first neutral energy value and a second neutral energy value, for which the total electron yield equals 1, i.e. there is no charging. According to some embodiments, which can be combined with other embodiments described herein, the surface of the packaging substrate can be read, i.e. signal electrons can be detected, with an electron beam having one of the neutral energy values.

According to some embodiments, which can be combined with other embodiments described herein, directing an electron-beam with the first landing energy on a portion of a packaging substrate can be a charging operation. The charging operation “writes” a charge to an electrical interconnect path or a network of electrical interconnect paths. Further, directing an electron-beam with a second landing energy on a portion of the packaging substrate can be an operation for detecting signal electrons. The electron beam at the second landing energy may “read” a charge of an electrical interconnect path or a network of electrical interconnect paths.

According to some embodiments, which can be combined with other embodiments described herein, charging of portions of the packaging substrate is reduced or avoided during detection of signal electrons, i.e. reading of a charge. Particularly, influencing of a charge of electrical interconnect path or network of electrical interconnect paths is avoided or kept to a minimum while detecting signal electrons, for example, detecting the charge previously provided.

For example, a network of electrical interconnect paths may include 5 surface contact points (or any number lager than 2). A charge can be applied, i.e. “written”, to a first surface contact point. The charge applied to the network of electrical interconnect paths can be “read” at a second surface contact point. It is beneficial not to change the charge of the network of electrical interconnect paths having the 5 surface contact points while “reading”, the charge on the second to fifth surface contact point. Accordingly, charge generation can be reduced or avoided during detecting signal electrons by utilizing a neutral energy value for the landing energy.

The neutral energy values are material dependent. The material of the packaging substrate or a material of the surface of the packaging substrate is known and the landing energies can be adapted to the packaging substrate material for methods of testing the packaging substrate. The first neutral energy value can be a few hundred eV. The second neutral energy value can be between 1.5 keV and 2.5 keV for typical packaging substrates or typical surface contact points on a packaging substrate. According to some embodiments, which can be combined with other embodiments described herein, the landing energy for test methods can be chosen to be above the second neutral energy value for charging, to be between the first neutral energy value and the second neutral energy value for charging, or to be below the first neutral energy value. The landing energy can be adapted depending on the test strategy, the material of the packaging substrate, and/or the material of the surface contact points.

For landing energies below the first neutral energy value, negative charging occurs, i.e. the total electron yield is smaller than 1. For landing energies between the first neutral energy value and the second neutral energy value, positive charging occurs, i.e. the total electron yield is larger than 1. The total electron yield being larger than 1 relates to the fact that more electrons leave the surface as compared to the number of electrons impinging on the surface. Thus, the packaging substrate or structures charge positively. For landing energies above the second neutral energy value, negative charging occurs, i.e. the total electron yield is smaller than 1. The total electron yield being smaller than 1 relates to the fact that less electrons leave the surface as compared to the number of electrons impinging on the surface. The packaging substrates or structures charge negatively.

According to embodiments of the present disclosure, test structures, for example, regions of a packaging substrate and/or surface contact points can be charged positive or negative by the electron beam impact. Depending on the primary energy level, i.e. the landing energy, in relation to the secondary electron yield, the total electron yield can be controlled. The test point potential can be determined. A voltage contrast principle can be utilized for defect detection. Further, sample parameter monitoring (such as capacitance resistance) can be provided. According to some embodiments, which can be combined with other embodiments described herein, the landing energy can be changed to be higher or lower than the second neutral energy value. The landing energy of the electron beam is set to a predetermined landing energy and positioned on a portion of the packaging substrate, for example, the surface contact point or test point on the packaging substrate. The electron-beam remains on the portion of the packaging substrate for a defined time to charge the portion of the packaging substrate positive or negative with respect to the environment of the portion of the packaging substrate. For example, the environment of a surface contact point under test can be one or more neighboring surface contact points.

According to an embodiment, a method for testing a packaging substrate with at least one electron beam column is provided. The packaging substrate is a panel level packaging substrate or an advanced packaging substrate. The method includes placing the packaging substrate on a stage in a vacuum chamber; flooding at least portions of the vacuum chamber with positive ions and/or negative charges; generating an electric field between one or more electrodes and the packaging substrate, the electric field being configured to accelerate the positive ions or negative charges towards the substrate; testing the packaging substrate in the vacuum chamber.

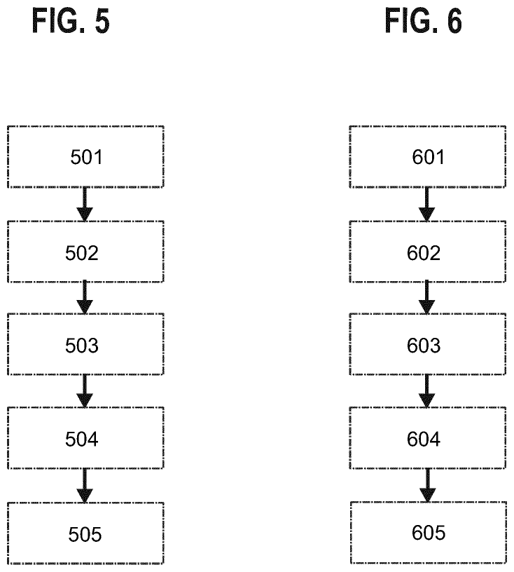

A packaging substrate as described herein can be a panel level packaging substrate or an advanced packaging substrate. As illustrated in FIG. 5, the method is conducted with an electron beam column and includes (see operation 501) placing the packaging substrate on a stage in a vacuum chamber. At operation 502, ions are generated within the vacuum chamber. Particularly positive ions and/or negative charges are generated, which may flood at least portions of the vacuum chamber. At operation 503, an electric field is generated between, for example, electrode, a first plurality of electrodes 146, and/or a second plurality of electrodes 148 and the packaging substrate. Generating an electric field between one or more electrodes and the packaging substrate accelerates the positive ions or negative charges towards the substrate. The charges serve for charge control, particularly with a self-aligning process. At operation 504, the packaging substrate is tested in the vacuum chamber.

For testing, at least one electron beam of the at least one electron beam column is directed on at least a first portion of the packaging substrate and at least one electron beam of the at least one electron beam column is directed on at least a second portion of the packaging substrate. Signal electrons emitted upon impingement of the at least one electron beam are detected for testing a first device-to-device electrical interconnect path of the packaging substrate.

According to some embodiments, which can be combined with other embodiments described herein, the at least one electron beam can be directed on the at least first portion with a first landing energy and on the at least second portion with a second landing energy different than the first charging landing energy. For example, the signal electrons can be detected upon impingement of the at least one electron beam with the second landing energy for reading of a charge on the packaging substrate. For example, the second landing energy can be at or close to or neutral energy value. For example, the reading landing energy deviates by less than +−10% from a neutral energy value, the neutral energy value corresponding to a landing energy with a total electron yield of 1

According to some embodiments, which can be combined with other embodiments described herein, the at least one electron beam can be focused while directing the electron beam on at least the first portion of the packaging substrate and on at least the second portion of the packaging substrate. According to yet further modifications, which can be combined with embodiments of the present disclosure, the electron beam is canned to one or more positions on the packaging substrate for charging and for detecting the signal electrons. Yet further, additionally or alternatively, a method may include energy filtering the signal electrons.

Embodiments of the present disclosure can include a method for testing a packaging substrate as illustrated by the flowchart shown in FIG. 6. At operation 601, and advanced packaging substrate or panel level packaging substrate can be loaded in a test chamber, for example, in the vacuum chamber 110 shown in FIG. 1B. At operation 602, the packaging substrate is moved below the electron beam column. The electron-beam test or electron-beam test sequence may include charging of test points and reading of test points, i.e. surface contact points on the packaging substrate. Testing of the packaging substrate may include directing at least one electron beam of the at least one electron beam column on at least a first portion of the packaging substrate; directing the at least one electron beam of the at least one electron beam column on at least a second portion of the packaging substrate; and detecting signal electrons emitted upon impingement of the at least one electron beam for testing a first device-to-device electrical interconnect path of the packaging substrate.

For example, the at least one electron beam can be directed on at least the first portion with a first landing energy and on at least the second portion with a second landing energy different than the first landing energy. The signal electrons are detected upon impingement of the at least one electron beam with the second landing energy for reading of a charge on the packaging substrate.

At operation 603, the vacuum chamber or at least a portion of the vacuum chamber, particularly adjacent the packaging substrate is flooded with ions. Accordingly, the ions can fly between the packaging substrate and the positive or negative electrode. The electrode can be an electrode utilized during operation of the charged particle beam column. The electrical field provided between the substrate and the electrode accelerate positive ions or negative charges towards the packaging substrate. Particles with an opposite charge are attracted by the electrode, for example, an electrode or portion of the charged particle beam column. At operation 604 the charges neutralize charge on the packaging substrate. The packaging substrate can be set to a defined charge condition. For example, the packaging substrate can be set to a defined potential relative to ground. At operation 605, the ion source can be turned off. Further the electric field can be turned off or changed in a mode for testing operation. Electron-beam test is provided with charging of contact points and reading of contact points.

According to some embodiments, which can be combined with other embodiments described herein, operations 603 and 604, may be provided during an electron-beam test sequence or between different electron-beam test sequence. An intermediate ion discharge steps can be provided during testing of the packaging substrate. The charge control as described herein provides an improved signal to noise ratio for the testing of packaging substrates with an electron-beam due to defined starting conditions of the contact points or test points, particularly of all contact points or test points. A uniform an integral charge control method of an entire test area can be provided. Further, as the charge control process is self-aligning, a homogeneously charged packaging substrate can be provided. The self-aligning is inter alia based on the fact that, for example, more negatively charged areas attract more positive ions until an equilibrium is reached all over the packaging substrate. As described above, the testing operation according to embodiments of the present disclosure is contact free and can be provided independent from test feature dimensions and/or topography.

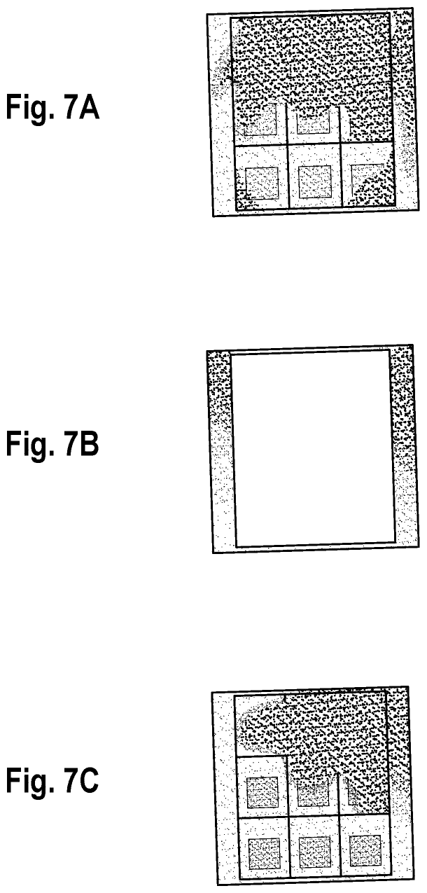

FIGS. 7A to 7C show the effect of charge control according to embodiments of the present disclosure. As shown in FIG. 7A, without pre-conditioning by ions an image generated with the charged particle beam column shows poor uniformity and higher noise. Accordingly, different electron-beam positions on the packaging substrate result in different signal levels. A correlation between the sample potential and the voltage contrast measured the signal electrons is reduced. FIG. 7B shows a similar image with preconditioning. For example, a pressure of about 5*10⁻³ Pa to about 1*10⁻¹ Pa, such as about 5*10⁻² Pa in the vacuum chamber results in an ion density for beneficial charge control. The SEM image shows improved uniformity and lower signal noise. Different electron beam positioning on the packaging substrate would result in the same signal level. A good correlation between sample potential and voltage contrast measurement can be provided. At lower pressures, for example, of about 5*10⁻⁴ Pa, the ion density is lower and may not result in efficient sample discharge at such a pressure. The image shown in FIG. 7C shows almost no improved uniformity or signal noise ratio improvement. Accordingly, embodiments of the present disclosure can result in better defect detectability and more precise parametric measurements, for example, a capacity.

Embodiments of the present disclosure provide for electron beam testing, and particularly including electron-beam writing and electron beam reading of charges on the packaging substrate, particularly to generate a defined measurement condition and/or starting condition. According to some embodiments, which can be combined with other embodiments described herein, the at least one electron beam can be focused while directing the electron beam on the at least first portion of the packaging substrate and on the at least second portion of the packaging substrate. Additionally or alternatively, the electron beam can be scanned to one or more positions on the packaging substrate for charging and for detecting the signal electrons.

Embodiments of the present disclosure provide one or more of the following advantages. A contact free electrical test of packaging substrates as disclosed herein can be provided, wherein electrical charge can be controlled for electrical defect detection. In light of the flexibility of the electron-beam, increased testing speed can be provided. An improved signal to noise ratio can be provided due to the defined conditions for various or all test points, i.e. surface contact points. An integral and uniform charge control method of the full test area can be provided. The charge control is self-aligning. A test including 100% of the electrical interconnection path is possible during volume production. Further, the flexibility of the electron-beam allows for testing and flexible setup for different AP/PLP substrate layouts. The test methods and apparatuses disclosed herein are independent from test feature dimensions and further allow for being scalable to smaller dimensions, particularly if technical development moves towards smaller structure sizes. The testing of the packaging substrates is damage free.

While the foregoing is directed to some embodiments, other and further embodiments may be devised without departing from the basic scope thereof, and the scope thereof is determined by the claims that follow.

1. A method for testing a packaging substrate for multi-device in-package integration with at least one electron beam column, the method comprising:
placing the packaging substrate on a stage in a vacuum chamber;
flooding at least portions of the vacuum chamber with positive ions and/or negative charges;
generating an electric field between one or more electrodes and the packaging substrate, the electric field being configured to accelerate the positive ions or the negative charges towards the substrate; and
testing the packaging substrate in the vacuum chamber with at least one electron beam column, wherein the flooding of the vacuum chamber with positive ions and/or negative charges is provided by an ion source at least partially provided in the vacuum chamber.

2. (canceled)

3. The method of claim 1, wherein the ion source is selected from the group consisting of:
an ion source with a gas supply, a VUV source, a spark generating the positive ion source.

4. The method of claim 1, wherein the electric field is uniform at a surface of the packaging substrate or wherein the electric field is uniform between the surface of the packaging substrate and the one or more electrodes.

5. The method of claim 1, wherein a gap is provided between the one or more electrodes and the packaging substrate.

6. The method of claim 1, wherein a gap is provided between the at least one electron beam column and the packaging substrate.

7. The method of claim 1, wherein the testing of the packaging substrate comprises:
directing at least one electron beam of the at least one electron beam column on at least a first portion of the packaging substrate;
directing the at least one electron beam of the at least one electron beam column on at least a second portion of the packaging substrate; and
detecting signal electrons emitted upon impingement of the at least one electron beam for testing a first device-to-device electrical interconnect path of the packaging substrate.

8. The method of claim 7, wherein the at least one electron beam is directed on at least the first portion with a first landing energy and on at least the second portion with a second landing energy different than the first landing energy.

9. The method of claim 8, wherein the signal electrons are detected upon impingement of the at least one electron beam with the second landing energy for reading of a charge on the packaging substrate.

10. An apparatus for testing a packaging substrate in accordance with the method of claim 1.

11. An apparatus for contactless testing of a packaging substrate for multidevice in-package integration, comprising:
a vacuum chamber;
a stage within the vacuum chamber, the stage being configured to support the packaging substrate;
a charged particle beam column configured to generate an electron beam, the charged particle beam column comprising:
an objective lens configured to focus the electron beam on the packaging substrate;
a scanner configured to scan the electron beam to different positions on the packaging substrate; and
an electron detector for detecting signal electrons emitted upon impingement of the electron beam on the packaging substrate;
the apparatus further comprising:
an ion source at least partially provided in the vacuum chamber for flooding the vacuum chamber with positive ions and/or negative charges;
one or more electrodes configured to generate an electric field between one or more electrodes and the packaging substrate, the electric field being configured to accelerate positive ions or negative charges towards the substrate; and
an analysis unit for determining, based on the signal electrons, if a first device-to-device electrical interconnect path is defective.

12. The apparatus of claim 11, wherein the one or more electrodes are provided in the charged particle beam column.

13. The apparatus of claim 12, wherein the one or more electrodes are positioned to guide signal electrons towards the detector.

14. The apparatus according to claim 11, wherein the one or more electrodes are at least one assembly of four or eight electrodes configured to generate a multipole field for guiding signal electrons.

15. The apparatus of claim 11, wherein the stage comprises:
a conductive stage surface connected directly or indirectly to ground for providing a reference potential.

16. The apparatus of claim 11, wherein the electron detector comprises:
an energy filter for the signal electrons.

17. The apparatus of claim 11, further comprising:
a scan controller configured to sequentially direct the electron beam to pairs of first and second surface contact points for testing respective device-to-device electrical interconnect paths extending between the respective pairs of first and second surface contact points.
